(19) United States
(12) Patent Application Publication
(10) Pub. No.: US 2018/0284603 A1
(43) Pub. Date: Oct. 4, 2018

(54) OUTER MASK, PLASMA PROCESSING APPARATUS, AND MANUFACTURING METHOD OF PHOTO MASK

(71) Applicant: Shibaura Mechatronics Corporation, Yokohama-shi (JP)

(72) Inventors: Yoshinori Iino, Yokohama (JP); Takashi Miyamoto, Yokohama (JP)

(21) Appl. No.: 15/941,174

(22) Filed: Mar. 30, 2018

(30) Foreign Application Priority Data
Mar. 31, 2017 (JP) 2017-071129

(51) Int. Cl. G03F 1/80; H01J 37/32; G03F 1/26; G03F 1/76; B23K 10/00

(52) U.S. Cl. CPC G03F 1/80; H01J 37/32743; H01J 2237/334; G03F 1/76; B23K 10/00; G03F 1/26

(57) ABSTRACT

An outer mask used when manufacturing a photo mask by etching an object to be processed, the object having a surface on which a pattern portion is provided, the outer mask includes: a base portion exhibiting a plate shape and including an opening in a central region, and a frame portion exhibiting a frame shape and provided along a periphery of the base portion. The frame portion has a surface which contacts the surface of the object at four corners of the surface of the object.

### CROSS-REFERENCE TO RELATED APPLICATIONS

This application is based upon and claims the benefit of priority from Japanese Patent Application No. 2017-071129, filed on Mar. 31, 2017; the entire contents of which are incorporated herein by reference.

### BACKGROUND

### Field

The embodiment of the invention relates to an outer mask, a plasma processing apparatus, and a manufacturing method of photo mask.

### Description of the Related Art

A microstructure such as a semiconductor device is manufactured using a photolithography method. In a photolithography method, exposure is carried out using a photo mask. In recent years, phase shift masks that improve transcription properties by improving resolution or depth of focus in exposure, reflective masks used in EUV lithography, which carries out transcription of a fine pattern using extreme ultra violet (EUV), or the like are proposed to replace binary masks.

Photolithography methods are also used when manufacturing phase shift masks or reflective masks. For example, when manufacturing a phase shift mask, a resist mask is formed by forming a layer including molybdenum silicon (MoSi) on a base portion made up of quartz, forming a layer including chromium (Cr) on the layer including molybdenum silicon, applying a photo-resist on the layer including chromium, and carrying out patterning using a photolithography method and the like, a desired pattern is formed on the layer including chromium and the layer including molybdenum silicon is formed by dry etching using a resist mask as the etching mask, and after this, the layer including chromium on the pattern including molybdenum silicon is removed by forming a resist mask once again and dry etching.

Meanwhile, when removing the layer including chromium, residue including chromium may remain on the pattern including molybdenum silicon. When there is residue including chromium, optical properties such as permeability change and the function of the phase shift mask decrease, thereby making it necessary to remove the residue including chromium. Because of this, when residue including chromium remains, a resist mask is formed once again by re-applying a photo-resist and patterning using a photolithography method or the like, and the residue including chromium is removed by dry etching once again using a resist mask as the etching mask.

In this manner, residue including chromium can be removed. However, re-applying the photo-resist and patterning requires time, causing decrease in productivity.

Here, a technology for removing a layer in a desired region by providing a shutter that opposes an object to be processed inside a processing container of the plasma processing apparatus and changing the size of the opening of the shutter is proposed (for example, see Patent Literature 1).

In a case where this technique is used when removing the residue including chromium, it is no longer necessary to re-apply the photo-resist and carry out patterning.

However, by simply making a shutter opposing the object to be processed, there is a risk in that a radical (neutral active type) supplied via the opening of the shutter may reach the surface of the layer including chromium on the outer side of the pattern including molybdenum silicon, and a radical wrapped around the side of the shutter may reach the surface of the layer including chromium on the outer side of the pattern including molybdenum silicon. When a radical reaches the surface of the layer including chromium, the layer including chromium is etched and the function of the phase shift mask may decrease.

Therefore, development of a technology in which a decrease in functionality of the photo mask can be suppressed, and in which productivity can be improved is desired.

### CITATION LIST

### Patent Literature

Patent Literature 1: JP 5696418 B

### SUMMARY

An outer mask used when manufacturing a photo mask by etching an object to be processed, the object having a surface on which a pattern portion is provided, the outer mask includes: a base portion exhibiting a plate shape and including an opening in a central region, and a frame portion exhibiting a frame shape and provided along a periphery of the base portion. The frame portion has a surface which contacts the surface of the object at four corners of the surface of the object.

### BRIEF DESCRIPTION OF THE DRAWINGS

FIG. 1 is a layout diagram for illustrating a plasma processing apparatus.

FIG. 2 is a schematic cross-sectional view for illustrating an example of a processing part.

FIG. 3A is a schematic perspective view for illustrating an outer mask mounted on an object to be processed. FIG. 3B is a schematic cross-sectional view for illustrating the positional relationship between an outer mask and a pattern portion of an object to be processed. FIG. 3C is a schematic cross-sectional view of portion A in FIG. 3A. FIG. 3D is a schematic enlarged view of portion B in FIG. 3A. FIG. 3E is a schematic enlarged view of portion C in FIG. 3A. FIG. 3F is a schematic cross-sectional view viewing FIG. 3A from the bottom surface side (side mounted to the object to be processed).

FIG. 4 is a schematic cross-sectional view for illustrating the outer mask according to another embodiment.

FIGS. 5A to 5K are schematic process cross-sectional views for illustrating a manufacturing method of a phase shift mask according to a comparative example.

FIGS. 6A and 6B are schematic process cross-sectional views for illustrating a manufacturing method of a phase shift mask according to the embodiment.

### DETAILED DESCRIPTION

Embodiments will now be described with reference to the drawings. The same numerals are applied to similar constituent elements in the drawings, and a detailed description thereof is appropriately omitted.

### Plasma Processing Apparatus 1

First, a plasma processing apparatus 1 according to an embodiment of the invention will be described.

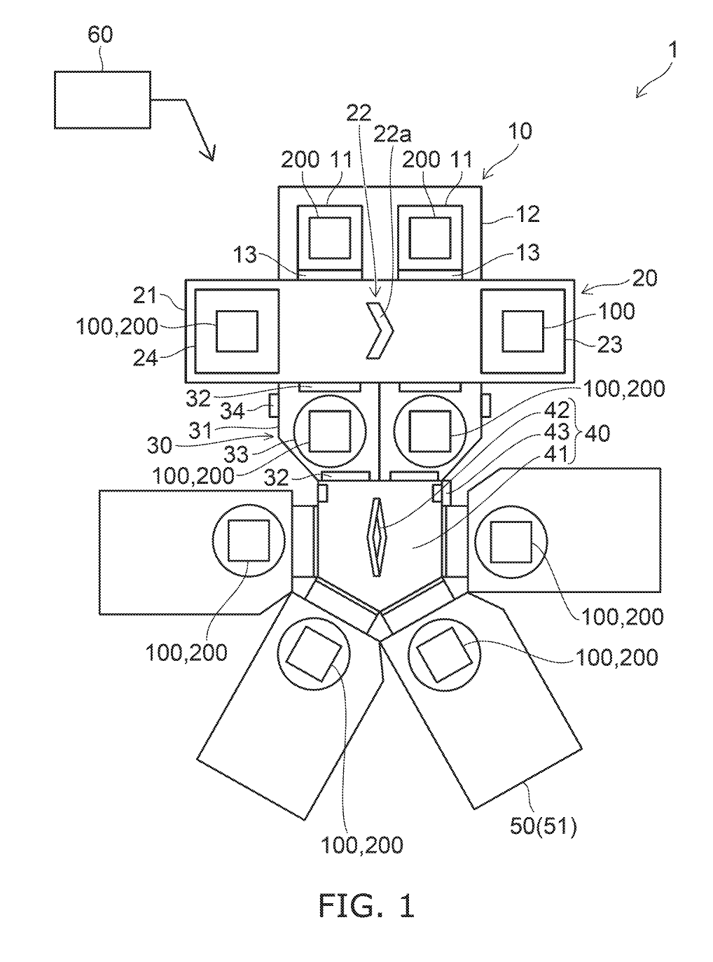

FIG. 1 is a layout diagram for illustrating the plasma processing apparatus 1.

As illustrated in FIG. 1, an accumulating part 10, a transport part 20, a load lock part 30, a delivery part 40, a processing part 50, and a control part 60 are provided in the plasma processing apparatus 1.

The flat surface shape of an object to be processed 200 on which plasma etching processing is performed by the plasma processing apparatus 1 is, for example, a square shape. Furthermore, the plasma processing apparatus 1 can be made into an apparatus that manufactures a phase shift mask or a reflective mask by carrying out plasma etching processing on the object to be processed 200. Details of the object to be processed 200 will be described hereinafter.

A storage part 11, a stand 12, and an opening and closing door 13 are provided in the accumulating part 10.

The storage part 11 stores the object to be processed 200.

The number of storage parts 11 is not particularly limited, but productivity can be improved in a case where a plurality of the storage part 11 is provided. The storage part 11, for example, can be made into a carrier that can house the object to be processed 200 in stacks (multiple steps). For example, the storage part 11 can be made into a front-opening unified pod (FOUP), which is a front-opening carrier with the purpose of transporting and storing a substrate used in a mini environment semiconductor factory or the like.

However, the storage part 11 is not limited to an FOUP or the like as long as it can house the object to be processed 200.

The stand 12 is provided on the side surface of a floor surface or housing 21. The storage part 11 is mounted on the upper surface of the stand 12. The stand 12 holds the mounted storage part 11.

The opening and closing door 13 is provided between an opening of the storage part 11 and an opening of the housing 21 of the transport part 20. The opening and closing door 13 opens and closes the opening of the storage part 11. For example, the opening of the storage part 11 is sealed by raising the opening and closing door 13 by a driving part not illustrated. Furthermore, the opening of the storage part 11 is opened by lowering the opening and closing door 13 by a driving part not illustrated.

The transport part 20 is provided between the accumulating part 10 and the load lock part 30.

The transport part 20 transports the object to be processed 200 and an outer mask 100 in an environment having a pressure (for example, atmospheric pressure) higher than the pressure when carrying out plasma processing.

The housing 21, a transfer part 22, an outer mask storage part 23, and a mounting part 24 are provided in the transport part 20.

The housing 21, exhibits a box shape, and has the transfer part 22, the outer mask storage part 23, and the mounting part 24 provided therein. The housing 21, for example, can have an airtight structure to the extent that particles or the like cannot infiltrate from the exterior. The atmosphere in the housing 21 is, for example, at atmospheric pressure.

The transfer part 22 carries out the transport and delivery of the object to be processed 200 between the accumulating part 10 and the load lock part 30. The transfer part 22 can be made into a transport robot including an arm 22a that rotates around a pivot axis. The transfer part 22, for example, has a mechanism combining a timing belt and a link or the like. The arm 22a has a joint. A holding portion is provided on the tip end of the arm 22a to hold the object to be processed 200 or the outer mask 100.

The outer mask storage part 23 stores the outer mask 100. The number of outer masks 100 stored in the outer mask storage part 23 can be one or more. When storing a plurality of the outer mask 100, a plurality of shelves that mount the outer masks 100 can be provided in stacks (multiple steps). A plurality of similar outer masks 100 may be stored in the outer mask storage part 23, or a plurality of types of outer masks 100 having different opening dimensions or outer diameter dimensions may be stored.

The mounting part 24 supports the object to be processed 200. When processing the object to be processed 200, the transfer part 22 removes the object to be processed 200 from the storage part 11 and mounts it on the mounting part 24. Next, the transfer part 22 removes the outer mask 100 from the outer mask storage part 23, and mounts the outer mask 100 on the object to be processed 200 supported by the mounting part 24. When storing an object to be processed 200 that has been processed in the storage part 11, the transfer part 22 removes the object to be processed 200 to which the outer mask 100 is mounted from a mounting part 33 of the load lock part 30 and mounts it on the mounting part 24. Next, the transfer part 22 removes the outer mask 100 from the object to be processed 200 by raising the outer mask 100 upward, and stores the outer mask 100 in the outer mask storage part 23. Next, the transfer part 22 removes the object to be processed 200 from the mounting part 24 and stores the object to be processed 200 in the storage part 11.

Details of the outer mask 100 will be described hereinafter.

The load lock part 30 is provided between the transport part 20 and the delivery part 40.

The load lock part 30, for example, is made to be able to deliver the object to be processed 200 to which the outer mask 100 is mounted, between the housing 21 in which the atmosphere is at atmospheric pressure, and a housing 41 in which the atmosphere is at the pressure when carrying out plasma processing.

A load lock chamber 31, a door 32, the mounting part 33, and a pressure control part 34 are provided in the load lock part 30.

The load lock chamber 31 exhibits a box shape, and can maintain an atmosphere decompressed to less than atmospheric pressure.

The door 32 is provided on each of the housing 21 side and a housing 41 side of the load lock chamber 31. Furthermore, the opening of the load lock chamber 31 can be opened and closed by moving the door 32 using a driving part not illustrated.

Furthermore, in a planar view, the position of the door 32 on the housing 41 side may be displaced from the position of the door 32 on the housing 21 side. In this case, the center of the door 32 on the housing 41 side can be made to be closer to the center side of a transfer part 42 than the center of the door 32 on the housing 21 side. In this manner, the transfer part 42 can easily infiltrate into the load lock chamber 31 when delivering the object to be processed 200 to which the outer mask 100 is mounted between the transfer part 42 and the load lock chamber 31.

The mounting part 33 is provided in the load lock chamber 31. The mounting part 33 supports the object to be processed 200 to which the outer mask 100 is mounted to be level.

The pressure control part 34 has a decompression part and a gas supply part.

The decompression part discharges gas in the load lock chamber 31, and decompresses the atmosphere in the load lock chamber 31 to a prescribed pressure lower than atmospheric pressure. For example, the pressure control part 34 makes it so that the pressure of the atmosphere in the load lock chamber 31 is substantially the same as the pressure of the atmosphere in the housing 41 (pressure when carrying out plasma processing).

The gas supply part supplies gas in the load lock part 31, and makes it so that the pressure of the atmosphere in the load lock chamber 31 is substantially the same as the pressure of the atmosphere in the housing 21. The gas supply part, for example, supplies gas in the load lock chamber 31, and returns the atmosphere in the load lock chamber 31 to atmospheric pressure from a pressure lower than atmospheric pressure.

By changing the pressure of the atmosphere in the load lock chamber 31 in this manner, the object to be processed 200 to which the outer mask 100 is mounted can be delivered between the housing 21 and the housing 41, which have different pressures of atmosphere.

The decompression part, for example, can be made into a vacuum pump or the like. The gas supply part, for example, can be made into a cylinder or the like in which a pressurized nitrogen gas, non-active gas, or the like is stored.

The delivery part 40 delivers the object to be processed 200 to which the outer mask 100 is mounted between the processing part 50 and the load lock part 30.

The housing 41, the transfer part 42, and a decompression part 43 are provided in the delivery part 40.

The housing 41 exhibits a square shape, with the interior thereof connected to the interior of the load lock chamber 31 via the door 32. The housing 41 can maintain an atmosphere decompressed to less than atmospheric pressure.

The transfer part 42 is provided in the housing 41. An arm including a joint is provided on the transfer part 42. A holding portion is provided on the tip end of the arm to hold the object to be processed 200 to which the outer mask 100 is mounted. The transfer part 42 holds the object to be processed 200 to which the outer mask 100 is mounted using the holding portion, changes the direction of the arm, and expands and contracts to bend the arm, thereby delivering the object to be processed 200 to which the outer mask 100 is mounted between the load lock chamber 31 and a processing container 51.

The decompression part 43 decompresses the atmosphere in the housing 41 to a prescribed pressure lower than atmospheric pressure. For example, the decompression part 43 makes it so that the pressure of the atmosphere in the housing 41 is substantially the same as the pressure when carrying out plasma processing in the processing container 51. The decompression part 43, for example, can be made into a vacuum pump or the like.

The processing part 50 carries out plasma processing on the object to be processed 200 to which the outer mask 100 is mounted in the processing container 51.

The processing part 50, for example, can be made into a plasma etching apparatus.

In this case, the plasma generation method is not particularly limited, and for example, can be made to generate plasma using high frequency, microwaves, or the like. Furthermore, the number of processing parts 50 is not particularly limited.

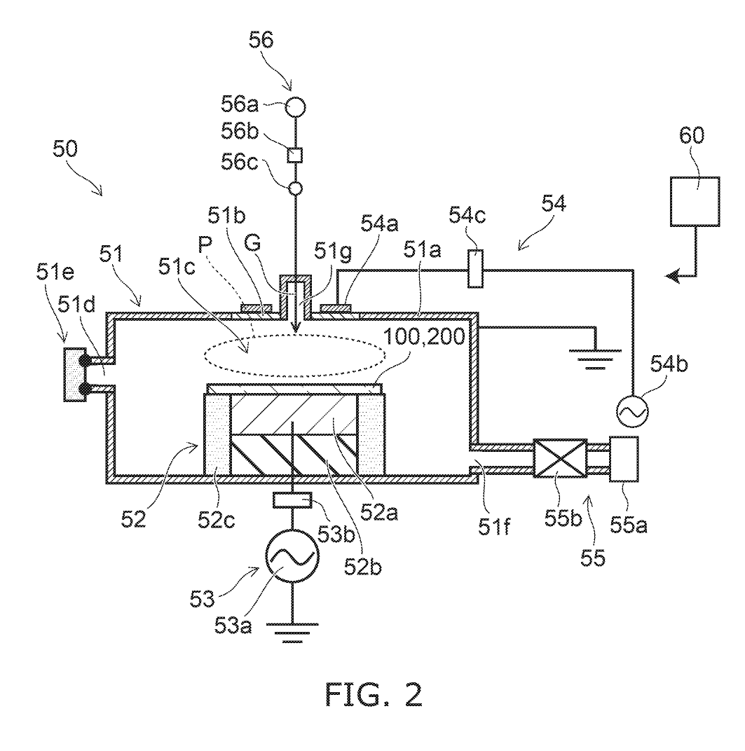

FIG. 2 is a schematic cross-sectional view for illustrating an example of a processing part.

As illustrated in FIG. 2, the processing container 51, a mounting part 52, a power source part 53, a power source part 54, a decompression part 55, and a gas supply part 56 are provided in the processing part 50.

The processing container 51 is an airtight structure that can maintain an atmosphere decompressed to less than atmospheric pressure.

The processing container 51 has a main body 51a and a window portion 51b.

The main body 51a exhibits a mostly cylindrical shape. The main body 51a, for example, can be formed of a metal such as an aluminum alloy. Furthermore, the main body 51a is grounded.

A plasma processing space 51c, which is a space for carrying out a plasma etching process on the object to be processed 200 to which the outer mask 100 is mounted, is provided in the main body 51a.

A carrying in/out opening 51d is provided on the main body 51a to carry in/out the object to be processed 200 to which the outer mask 100 is mounted.

The carry in/out opening 51d can be sealed airtight using a gate valve 51e.

The window part 51b exhibits a plate shape, and is provided on the ceiling plate of the main body 51a. The window part 51b can allow a magnetic field to permeate, and is formed of a material difficult to be etched when carrying out a plasma etching process. The window part 51b, for example, can be formed of a non-conductive material such as quartz.

The mounting part 52 is inside the processing container 51 and is provided on the bottom surface of the processing container 51 (main body 51a).

The mounting part 52 has an electrode 52a, a pedestal 52b, and an insulating ring 52c.

The electrode 52a is provided below the plasma processing space 51c. The upper surface of the electrode 52a is a mounting surface for mounting the object to be processed 200 to which the outer mask 100 is mounted. The electrode 52a can be formed of a conductive material such as metal.

The pedestal 52b is provided between the electrode 52a and the bottom surface of the main body 51a. The pedestal 52b is provided to insulate between the electrode 52a and the main body 51a. The pedestal 52b, for example, can be formed of a non-conductive material such as quartz.

The insulating ring 52c exhibits a ring shape, and is provided to cover a side surface of the electrode 52a and a side surface of the pedestal 52b. The insulating ring 52c, for example, can be formed of a non-conductive material such as quartz.

The power source part 53 has a power source 53a and a matching device 53b.

The power source part 53 is a so-called high frequency power source for controlling bias. That is, the power source part 53 is provided to control energy of ions taken into the object to be processed 200 to which the outer mask 100 is mounted on the mounting part 52. The electrode 52a and the power source 53a are electrically connected via the matching device 53b.

The power source 53a applies a high frequency power having a relatively low frequency appropriate for incorporating ions (for example, frequency of 13.56 MHz or less) to the electrode 52a.

The matching device 53b is provided between the electrode 52a and the power source 53a. The matching device 53b is provided with a matching circuit or the like to match impedance on a side of the power source 53a and impedance on a side of the plasma P.

The power source part 54 has an electrode 54a, a power source 54b, and a matching device 54c.

The power source part 54 is a high frequency power source for generating the plasma P. That is, the power source part 54 is provided to generate the plasma P by generating a high frequency discharge in the plasma processing space 51c.

In the embodiment, the power source part 54 is a plasma generating part generating the plasma P in the processing container 51.

The electrode 54a, the power source 54b, and the matching device 54c are electrically connected by wiring.

The electrode 54a is outside the processing container 51, and is provided on the window part 51b.

The electrode 54a can be made to include a plurality of a conductor generating a magnetic field and a plurality of a capacitor (condenser).

The power source 54b applies a high frequency power having a frequency of appropriately 100 KHz to 100 MHz to the electrode 54a. In this case, the power source 54b applies a high frequency power having a relatively low frequency appropriate for generating the plasma P (for example, frequency of 13.56 MHz or less) to the electrode 54a.

Furthermore, the power source 54b can be made to change the frequency of the high frequency power to be output.

The matching device 54c is provided between the electrode 54a and the power source 54b. The matching device 54c is provided with a matching circuit or the like to match impedance on a side of the power source 54b and impedance on a side of the plasma P.

The plasma processing apparatus 1 is a two frequency plasma etching apparatus including an inductively coupled electrode on the upper portion thereof and a capacitively coupled electrode on the lower portion thereof.

However, the generation method of plasma is not limited to that illustrated.

The plasma processing apparatus 1, for example, may be a plasma processing apparatus using inductively coupled plasma (ICP) or a plasma processing apparatus using capacitively coupled plasma (CCP).

The decompression part 55 has a pump 55a and a pressure control part 55b.

The decompression part 55 decompresses so that the interior of the processing container 51 is at a prescribed pressure. The pump 55a, for example, can be a turbo molecular pump (TMP) or the like. The pump 55a and the pressure control part 55b are connected via wiring.

The pressure control part 55b controls so that the internal pressure of the processing container 51 is at a prescribed pressure based on the output of a vacuum gauge or the like not illustrated, that detects the internal pressure of the processing container 51.

The pressure control part 55b, for example, can be an auto pressure controller (APC) or the like. The pressure control part 55b is connected to a discharge opening 51f provided on the main body 51a via wiring.

The gas supply part 56 supplies gas G to the plasma processing space 51c in the processing container 51.

The gas supply part 56 has a gas storage part 56a, a gas control part 56b, and a valve 56c.

The gas storage part 56a stores the gas G, and supplies the stored gas G into the processing container 51. The gas storage part 56a, for example, can be a high pressure pump or the like having gas G stored therein. The gas storage part 56a and the gas control part 56b are connected via wiring.

The gas control part 56b controls flow amount or pressure when supplying the gas G from the gas storage part 56a into the processing container 51. The gas control part 56b, for example, can be a mass flow controller (MFC) or the like. The gas control part 56b and the valve 56c are connected via wiring.

The valve 56c is connected to a gas supply opening 51g provided on the processing container 51 via wiring. The valve 56c controls the supply and suspension of the gas G. The valve 56c, for example, can be a two port solenoid valve or the like. The gas control part 56b can have the function of the valve 56c.

The gas G can generate a radical that can etch the object to be processed 200 when excited or activated by the plasma P. The gas G, for example, can be a gas including fluorine atoms. The gas G, for example, can be CHF₃, CF₄, C₄F₈ or the like.

The control part 60 is provided with an operating part such as a central processing part (CPU) and a memory part such as a memory.

The control part 60 controls the operation of each element provided in the plasma processing apparatus 1 based on the control program stored in the memory part. A detailed description will be omitted because a known technology can be applied to control programs controlling the operation of each element.

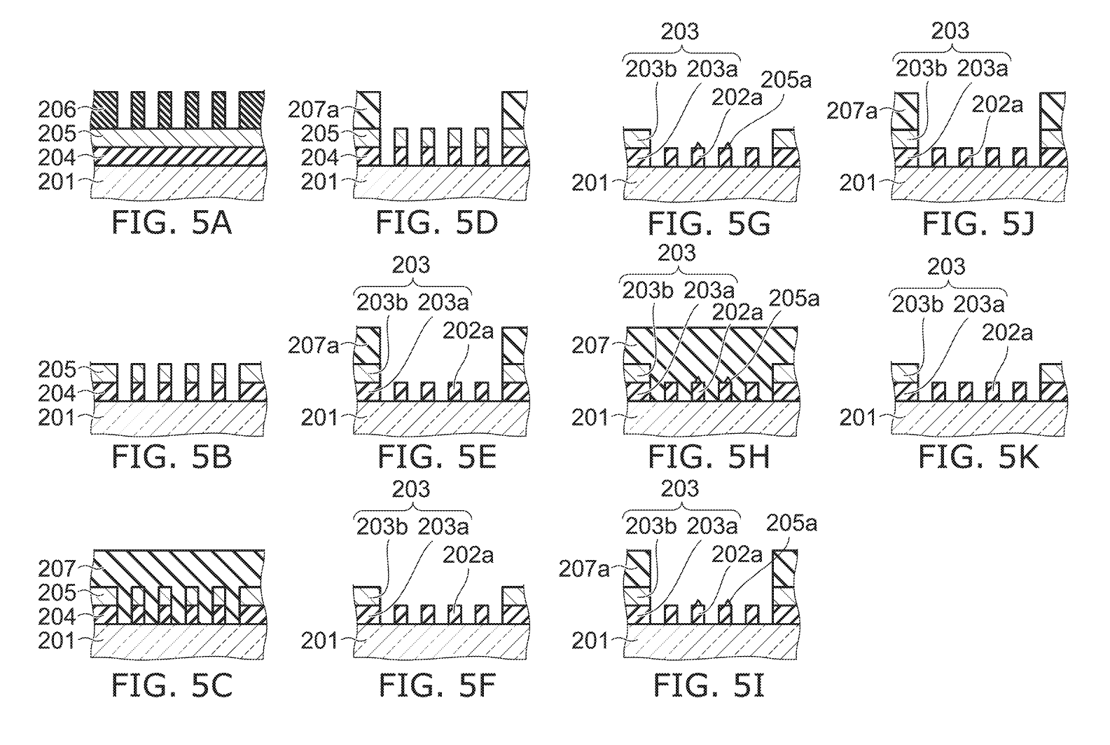

As described hereinafter, when manufacturing a phase shift mask, residue may remain on the surface of the object to be processed 200 having a pattern formed by etching. For example, as in FIG. 5G, a residue 205a may remain on a region to which a pattern portion 202 is provided by etching. In this case, the residue 205a can be removed in the plasma processing apparatus 1 in the following manner.

First, the transfer part 22 removes the object to be processed 200 having the residue 205a from the storage part 11 and mounts it on the mounting part 24. Next, the transfer part 22 removes the outer mask 100 from the outer mask storage part 23, and mounts the outer mask 100 on the object to be processed 200 supported by the mounting part 24.

Next, the transfer part 22 transfers the object to be processed 200 to which the outer mask 100 is mounted from the mounting part 24 to the mounting part 33 of the load lock part 30.

Next, the transfer part 42 transfers the object to be processed 200 to which the outer mask 100 is mounted from the mounting part 33 to the mounting part 52 in the processing container 51.

Next, the power source part 54 generates the plasma P by generating a high frequency discharge in the plasma processing space 51c. The gas supply part 56 supplies gas G to the plasma processing space 51c in the processing container 51.

The gas G is excited and activated by the plasma P, generating a reaction product such as a radical, ion, electron, or the like. The generated reaction product reaches the residue 205a via an opening 100a1 of the outer mask 100, and the residue 205a is removed.

An object to be processed 200 in which the residue 205a is removed with the outer mask 100 still mounted thereon is transferred from the mounting part 52 to the mounting part 24 opposite to the order described above. The transfer part 22 then removes the outer mask 100 from the object to be processed 200 by raising the outer mask 100 upward, and stores the outer mask 100 in the outer mask storage part 23. Next, the transfer part 22 removes the object to be processed 200 from the mounting part 24 and stores the object to be processed 200 in the storage part 11.

A detailed description will be omitted because a known technology can be applied for process conditions relating to etching.

### Outer Mask 100

The outer mask 100 will be further described.

The outer mask 100 is used in manufacturing a photo mask, that is, in the plasma etching process of the object to be processed 200. The outer mask 100 is a member having the function of shielding a region in which etching is not performed on the periphery of the object to be processed 200.

The object to be processed 200 will first be described.

The object to be processed 200, for example, can be a mask blank used for manufacturing a phase shift mask, or a mask blank used for manufacturing a reflective mask.

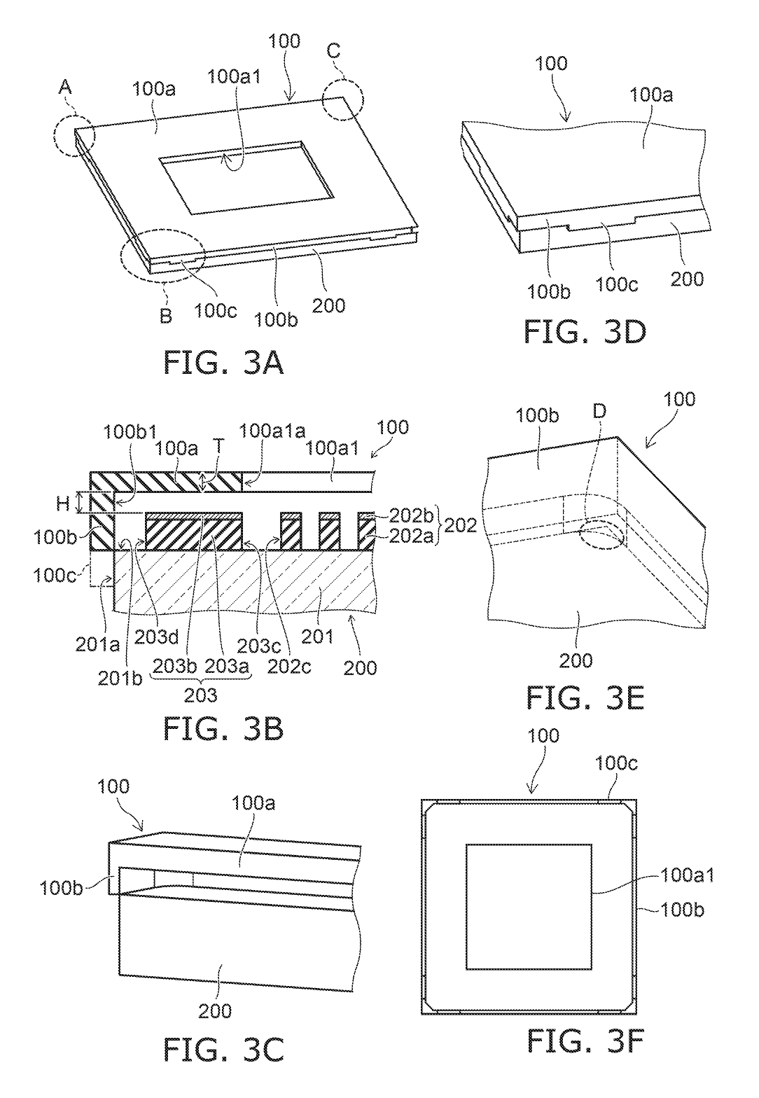

A case will be described below wherein the object to be processed 200 is a mask blank used for manufacturing a phase shift mask as an example. Furthermore, the object to be processed 200 will be described in the state of FIG. 3B described hereinafter, that is, a state in which the pattern portion 202 including a layer 202b including chromium, and a light shielding part 203 including a layer 203b including chromium are formed.

The object to be processed 200 has a substrate 201, a pattern portion 202, and a light shielding part 203 (for example, see FIG. 3B).

The substrate 201 exhibits a plate shape. The flat surface shape of the substrate 201, for example, can be a square shape. The substrate 201 has translucency, and is formed of a material that is difficult to be etched. The substrate 201, for example, can be formed of quartz.

The pattern portion 202 is provided on one surface of the substrate 201. The pattern portion 202 is provided on a central region of the substrate 201. The pattern portion 202 is provided on the substrate 201, and has a plurality of a protrusion 202a including molybdenum silicon. The layer 202b including chromium is provided on a top of each of the plurality of a protrusion 202a.

The light shielding part 203 is provided on an outer side of the region of the substrate 201 in which the pattern portion 202 is provided. The light shielding part 203 exhibits a frame shape and surrounds the region on which the pattern portion 202 is provided. The region on which the pattern portion 202 is provided is an outermost peripheral region of the pattern portion 202 (region including all of the pattern portion 202). The light shielding part 203 is provided on the substrate 201 and has a protrusion 203a including molybdenum silicon. The layer 203b including chromium is provided on a top of the protrusion 203a. In a planar view, a gap is provided between an outer peripheral end 203d of the frame shaped light shielding part 203 and a side surface 201a of the substrate 201. That is, the light shielding part 203 is not provided near the circumference of the substrate 201.

Next, the outer mask 100 will be described.

FIG. 3A is a schematic perspective view for illustrating the outer mask mounted on the object to be processed 200.

FIG. 3B is a schematic cross-sectional view for illustrating the positional relationship between the outer mask 100 and the pattern portion 202 of the object to be processed 200.

FIG. 3C is a schematic cross-sectional view of portion A in FIG. 3A. FIG. 3C is drawn omitting the pattern portion 202 and the light shielding part 203.

FIG. 3D is a schematic enlarged view of portion B in FIG. 3A.

FIG. 3E is a schematic enlarged view of portion C in FIG. 3A.

FIG. 3F is a schematic cross-sectional view viewing FIG. 3A from the bottom surface side (side mounted to the object to be processed 200). FIG. 3F is drawn omitting the object to be processed 200.

As illustrated in FIG. 3A, a base portion 100a, a frame portion 100b, and a stopper 100c are provided on the outer mask 100. The outer mask 100 has insulation, and is formed of a material that is difficult to be etched. The outer mask 100, for example, can be formed of quartz.

The base portion 100a exhibits a plate shape. The flat surface shape of the base portion 100a can be made the same flat surface shape of the object to be processed 200. For example, the flat surface shape of the base portion 100a can be a square shape when the flat surface shape of the object to be processed 200 is a square shape. Furthermore, the base portion 100a has the opening 100a1 on a central region thereof.

As illustrated in FIG. 3B, the opening 100a1 does not overlap with the light shielding part 203 in a planar view. In a planar view, the pattern portion 202 is provided in the opening 100a1. A peripheral edge 100a1a of the opening 100a1 should be provided between an inner peripheral edge 203c of the light shielding part 203 and an outer peripheral edge 202c of the pattern portion 202. In this case, when the distance between the peripheral edge 100a1a of the opening 100a1 and the inner peripheral edge 203c of the light shielding part 203 is made larger in a planar view, it becomes easier to suppress damage occurring on the layer 203b including chromium when etching the layer 202b including chromium.

Furthermore, in a case where a distance H between the top of the light shielding part 203 and a bottom surface of the base portion 100a (surface of the object to be processed 200 side) is too short, the layer 203b including chromium may be damaged by the contact of the light shielding part 203 and the base portion 100a due to deformation by oscillation when transporting, heat deformation when etching or the like. Meanwhile, in a case where the distance H is too large, it becomes easier for a radical to reach the gap between the top of the light shielding part 203 and the bottom surface of the base portion 100a, and the layer 203b including chromium may be damaged by reacting with the radical. According to information obtained by the inventors, damage to the layer 203b including chromium can be suppressed in a case where the distance H is made to be not less than 1 mm and not greater than 2 mm.

Furthermore, in a case where a thickness T of the base portion 201 is too thin, deformation by oscillation when transporting, heat deformation when etching, deformation when processing the outer mask 100 or the like may become larger. According to information obtain by the inventors, because deformation can be suppressed in a case where the thickness T of the base portion 100a is not less than 1 mm, damage to the layer 203b including chromium can be suppressed, and processing of the outer mask 100 can be made easier.

As illustrated in FIGS. 3A to 3C, the frame portion 100b exhibits a frame shape and protrudes from the bottom surface (surface of the object to be processed 200 side) of the base portion 100a. The frame portion 100b is provided along the peripheral edge of the base portion 100a. In a planar view, an inner peripheral edge 100b1 of the frame portion 100b and a side surface 201a of the substrate 201 of the object to be processed 200 overlap, or a slight gap is provided between the inner peripheral edge 100b1 of the frame portion 100b and the side surface 201a of the substrate 201 of the object to be processed 200. That is, in principle, the surface 201b of the substrate 201 to which the pattern portion 202 and the light shielding part 203 are provided, and a lower end 100b2 of the frame portion 100b do not contact.

However, as illustrated in FIG. 3E, the lower end 100b2 of the frame portion 100b can contact the surface 201b of the substrate 201 near the four corners of the surface 201b. For example, as illustrated in portion D of FIG. 3E or as in FIG. 3F, the four corners of the inner periphery of the frame portion 100b has a surface (R surface or inclined surface) protruding inward from a corner to which extended lines of two adjacent sides of the inner periphery of the frame portion 100b intersect, and the lower end 100b2 of the four corners of the frame portion 100b has a surface which the surface 201b contacts. Because of this, the frame portion 100b can contact the surface 201b on the four corners of the surface 201b of the substrate 201 of the object to be processed 200. In this manner, damage to the surface 201b of the substrate 201 can be suppressed, and the outer mask 100 can be supported by the object to be processed 200 because the object to be processed 200 and the outer mask 100 do not contact other than at the four corners of the surface 201b. In this case, the frame portion 100b can contact the surface 201b in a region within 5 mm of the corners of the surface 201b.

As illustrated in FIGS. 3A, 3B, and 3D, the stopper 100c protrudes from the lower end 100b2 of the frame portion 100b. At least one stopper 100c is provided on each of the four sides of the frame portion 100b. With that illustrated in FIG. 3A, two stoppers 100c are provided on each of the four sides of the frame portion 100b. In a case where such a stopper 100c is provided, the outer mask 100 can be suppressed from being displaced in the horizontal direction. A slight gap may be provided between the stopper 100c and the side surface 201a of the substrate 201, allowing movement to the extent of the gap.

As described hereinafter, when removing the residue 205a or layer 202b including chromium by etching, a reaction product such as a radical is supplied to the residue 205a or the layer 202b including chromium via the opening 100a1 of the outer mask 100. At this time, when the radical reaches the layer 203b including chromium provided on the light shielding part 203, the layer 203b including chromium is etched, and the layer 203b including chromium may be damaged. When the layer 203b including chromium is damaged, the function as a phase shift mask may decrease.

When using the outer mask 100 according to the embodiment, because the region to which the light shielding part 203 is provided is surrounded by the base portion 100a and the frame portion 100b, the flow (airflow) of gas including a reaction product such as a radical can be suppressed from reaching the surface 201b from the side surface 201a side. Furthermore, because the distance between the top of the light shielding part 203 and the bottom surface of the base portion 100a of the outer mask 100 (surface of the object to be processed 200 side) is extremely short, the flow (airflow) of gas including a reaction product such as a radical is shielded by the frame portion 100b. In this manner, airflow can be suppressed from being generated in the region to which the light shielding part 203 is provided. Because of this, the radical can be suppressed from being drawn to the upper portion of the layer 203b including chromium by this airflow. As a result, damage can be suppressed from occurring on the layer 203b including chromium, and a decrease in the function as a phase shift mask can be suppressed. Furthermore, as described hereinafter, productivity can be improved when removing residue including chromium because it is no longer necessary to re-apply the photo-resist and carry out patterning.

Furthermore, in principle, because the surface 201b of the substrate 201 and the lower end 100b2 of the frame portion 100b do not contact, damage such as flaws due to contacting the substrate 201 of the phase shift mask can be suppressed.

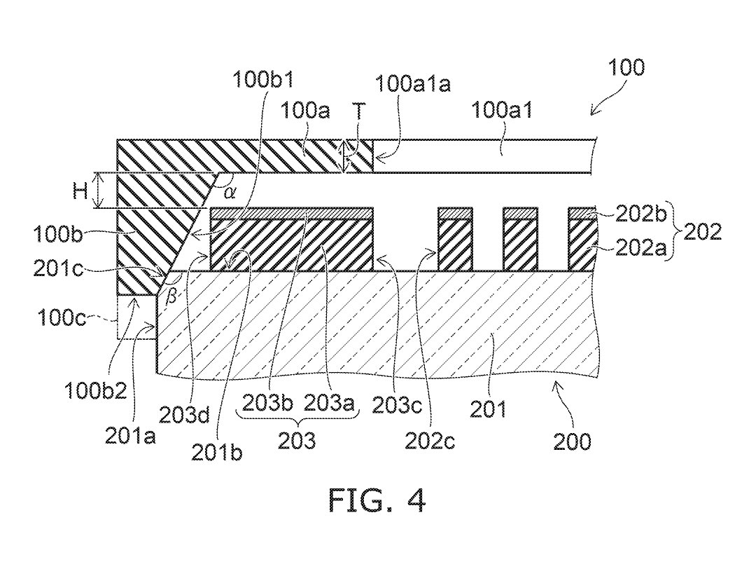

FIG. 4 is a schematic cross-sectional view for illustrating an outer mask 100 according to another embodiment.

As illustrated in FIG. 4, a beveling portion 201c is provided on the periphery of the surface 201b of the substrate 201 of the object to be processed 200. Furthermore, the inner peripheral edge 100b1 of the frame portion 100b of the outer mask 100 is an inclined surface. The inner peripheral edge 100b1 contacts the beveling portion 201c.

In this manner, an airflow can be further suppressed from occurring in the region to which the light shielding part 203 is provided. Therefore, damage of the layer 203b including chromium can be further suppressed, and a decrease in the function as a phase shift mask can be further suppressed. As illustrated in FIG. 4, the inclined angle α of the inner peripheral edge 100b1 and the inclined angle β of the beveling portion 201c can be made the same. In this manner, displacement can be suppressed when the outer mask 100 is mounted on the object to be processed 200.

### Manufacturing Method of Photo Mask

Next, a method for manufacturing the photo mask according to the embodiment will be described.

FIGS. 5A to 5K are schematic process cross-sectional views for illustrating a method for manufacturing a phase shift mask according to a comparative example.

First, as illustrated in FIG. 5A, a film 204 including molybdenum silicon, and a film 205 including chromium are formed in this order on one surface of the substrate 201, a resist is applied on the film 205 including chromium, and an etching mask 206 is formed using a photolithography method.

Next, as illustrated in FIG. 5B, the film 205 including chromium and the film 204 including molybdenum silicon exposed from the etching mask 206 are etched in this order, and the etching mask 206 is removed.

Next, as illustrated in FIG. 5C, a resist 207 is applied.

As illustrated in FIG. 5D, an etching mask 207a is then formed using a photolithography method.

As illustrated in FIG. 5E, the film 205 including chromium exposed from the etching mask 207a is then etched, and a plurality of a protrusion 202a is exposed.

As illustrated in FIG. 5F, the etching mask 207a is then removed.

A phase shift mask can be manufactured including the substrate 201, the plurality of a protrusion 202a, and the light shielding part 203 in the above manner.

However, when carrying out product inspection of a manufactured phase shift mask, the residue 205a including chromium may be detected on the top of the protrusion 202a as illustrated in FIG. 5G. The function as a phase shift mask decreases when there is the residue 205a including chromium.

Therefore, the residue 205a is removed in the following manner when the residue 205a has been detected.

First, as illustrated in FIG. 5H, the resist 207 is re-applied.

As illustrated in FIG. 5I, the etching mask 207a is then re-formed using a photolithography method.

As illustrated in FIG. 5J, the residue 205a exposed from the etching mask 207a is then etched.

As illustrated in FIG. 5K, the etching mask 207a is then removed again.

The residue 205a can be removed in the above manner.

However, it is necessary to re-apply the photo-resist 207, re-form the etching mask 207a using a photolithography method or the like, and remove the etching mask 207a yet again to remove the residue 205a. A relatively long period of time is necessary to carry out such a process. Therefore, this causes decreased productivity.

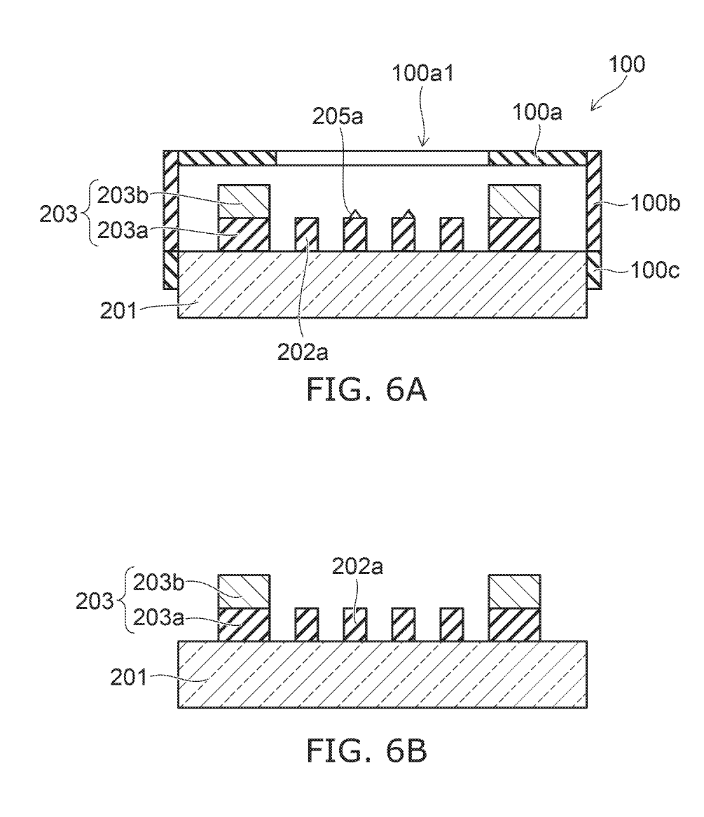

FIGS. 6A and 6B are schematic process cross-sectional views for illustrating a method for manufacturing a phase shift mask according to the embodiment.

In the method for manufacturing the phase shift mask according to the embodiment, the outer mask 100 is used when removing the residue 205a.

First, as illustrated in FIG. 6A, the outer mask 100 is mounted on the substrate 201. As illustrated in FIG. 6B, the residue 205a exposed in the opening 100a1 of the outer mask 100 is then etched.

The phase shift mask having the residue 205a removed can then be obtained by removing the outer mask 100 from the substrate 201.

In this manner, productivity can be greatly improved because the re-applying of the photo-resist 207, re-forming of the etching mask 207a, and the removal of the etching mask 207a again described above are not necessary to remove the residue 205a. As described above, damage can also be suppressed from occurring on the layer 203b including chromium.

An example was illustrated in which the outer mask 100 is used to remove the residue 205a, but the outer mask 100 can also be used when etching the film 205 including chromium illustrated in FIG. 5B.

In this manner, productivity can be even further improved because applying the photo-resist 207, forming the etching mask 207a, and removing the etching mask 207a are not necessary.

A detailed description will be omitted because a known technology can be applied for process conditions relating to the etching.

Embodiments will now be described with reference to the drawings. However, the invention is not limited to these examples.

Also, these examples to which a person skilled in the art to which the invention pertains has added design modifications as appropriate are also included in the scope of the invention, provided the features of the invention are included.

For example, each of the elements included in the plasma processing apparatus 1 and their shape, size, material, arrangement, number, and the like is not limited to the examples described above, but can be varied as appropriate.

Additionally, each element provided in each of the embodiments may be combined as far as possible, and insofar as those combinations include the characteristics of the invention, are within the scope of the invention.

What is claimed is:

1. An outer mask used when manufacturing a photo mask by etching an object to be processed, the object having a surface on which a pattern portion is provided, the outer mask comprising:
a base portion exhibiting a plate shape and including an opening in a central region, and
a frame portion exhibiting a frame shape and provided along a periphery of the base portion,
the frame portion having a surface which contacts the surface of the object at four corners of the surface of the object.

2. The outer mask according to claim 1, wherein:
a beveling portion is provided on a periphery of the surface provided with the pattern portion, and
the frame portion further has a surface which contacts the beveling portion.

3. The outer mask according to claim 1, wherein:
the pattern portion is provided at a central portion of the object, and
in a planar view, the pattern portion is provided in the opening when the frame portion contacts the surface of the object.

4. The outer mask according to claim 1, wherein:
the object further has a light shielding part exhibits a frame shape and surrounding the pattern portion, and
a region to which the light shielding part is provided is surrounded by the base portion and the frame portion when the frame portion contacts the surface of the object.

5. The outer mask according to claim 1, wherein a thickness of the base portion is not less than 1 mm.

6. The outer mask according to claim 1, wherein a distance between a surface of the base portion on a side of the object to be processed, and the object to be processed is not less than 1 mm when the frame portion contacts the surface.

7. A plasma processing apparatus, comprising:
a storage part storing an object to be processed;
an outer mask storage part storing the outer mask according to claim 1;
a transfer part mounting the outer mask removed from the outer mask storage part on the object to be processed removed from the storage part; and
a processing part carrying out plasma processing on the object to be processed to which the outer mask is mounted.

8. The plasma processing apparatus according to claim 7, wherein
the pattern portion is provided at a central portion of the object, and
in a planar view, the pattern portion is provided in the opening when the frame portion contacts the surface of the object.

9. The plasma processing apparatus according to claim 7, wherein:
the object further has a light shielding part exhibits a frame shape and surrounding the pattern portion, and
a region to which the light shielding part is provided is surrounded by the base portion and the frame portion when the frame portion contacts the surface of the object.

10. A method for manufacturing a photo mask by etching an object to be processed, the method comprising:
mounting the outer mask according to claim 1 on the object to be processed; and
carrying out plasma processing on the object to be processed to which the outer mask is mounted.

11. The method according to claim 10, wherein residue on a surface of the object to be processed is removed when carrying out the plasma processing.

12. The method according to claim 10, wherein a layer including chromium on a surface of the object to be processed is removed when carrying out the plasma processing.
